(19) United States
(12) Patent Application Publication
(10) Pub. No.: US 2020/0053869 A1
(43) Pub. Date: Feb. 13, 2020

(54) ELECTROMAGNETIC SHIELD

(71) Applicant: Top Victory Investments Limited, Hong Kong (HK)

(72) Inventor: Richard WANG, New Taipei City (TW)

(21) Appl. No.: 16/197,288

(22) Filed: Nov. 20, 2018

(30) Foreign Application Priority Data
Aug. 10, 2018 (TW) 107127933

(51) Int. Cl. H05K 1/02; H05K 9/00; H01L 23/552

(52) U.S. Cl. CPC H05K 1/0218; H05K 9/0024; H05K 9/0039; H05K 2201/10371; H05K 1/0203; H05K 2201/0707; H01L 23/552

(57) ABSTRACT

An electromagnetic shield is adapted to be mounted on a circuit board and to shield electromagnetic radiation produced by an electronic component. The electromagnetic shield includes a cover unit and a conductive surrounding wall. The cover unit includes a metallic main body having an abutment portion adapted to be connected to the electronic component. The conductive surrounding wall is connected to the cover unit, is adapted to abut tightly against the circuit board, and is adapted to cooperate with the main body and the circuit board to define an electromagnetic shielding space that encloses the electronic component.

### CROSS-REFERENCE TO RELATED APPLICATION

This application claims priority of Taiwanese Patent Application No. 107127933, filed on Aug. 10, 2018.

### FIELD

The disclosure relates to shield, more particularly to an electromagnetic shield.

### BACKGROUND

When an electronic device is in use, electronic components in the device may generate electromagnetic radiation which could interfere with the operation of other electronic devices. Referring to FIG. 1, a conventional electromagnetic shield includes a metallic casing 1. The casing I has a plurality of legs 11 and a plurality of heat-dissipating holes 12. The conventional electromagnetic shield is adapted to cover an electronic component on a circuit board. Once the leads 11 are soldered to the circuit board, the conventional electromagnetic shield may shield the electromagnetic radiation produced by the electronic component. The heat-dissipating holes 12 help to lower the temperature within the conventional electromagnetic shield. With the functionality and operating speed of current electronic devices growing rapidly, the conventional electromagnetic shield is becoming inadequate, only shielding against lower frequency electromagnetic radiation noises. Further, thermal convection is no longer efficient enough in cooling the temperature inside the electromagnetic shield.

### SUMMARY

Therefore, the object of the disclosure is to provide an electromagnetic shield that can alleviate at least one of the drawbacks of the prior art.

According to the disclosure, an electromagnetic shield is adapted to be mounted on a circuit board and to cover an electronic component disposed on the circuit board so as to shield electromagnetic radiation produced by the electronic component.

The electromagnetic shield includes a cover unit and a conductive surrounding wall.

The cover unit includes a metallic main body. The main body has a first surface, a second surface that is opposite to the first surface, and an abutment portion that protrudes from the first surface and that is adapted to be connected to the electronic component.

The conductive surrounding wall is connected to the cover unit, is adapted to abut tightly against the circuit board, and is adapted to cooperate with the main body and the circuit board to define an electromagnetic shielding space that encloses the electronic component.

### BRIEF DESCRIPTION OF THE DRAWINGS

Other features and advantages of the disclosure will become apparent in the following detailed description of the embodiment with reference to the accompanying drawings, of which:

FIG. 1 is a perspective view of a conventional electromagnetic shield;

FIG. 2 is a partly exploded perspective view of an embodiment of an electromagnetic shield according to the disclosure, a circuit board, and an electronic component;

FIG. 3 is a perspective view of the emobidment;

FIG. 4 is a sectional view taken along line IV-IV of FIG. 2;

FIG. 5 is a perspective view of a securing member of the embodiment;

FIG. 6 is an assembled perspective view of the embodiment, the circuit board, and the electronic component;

FIG. 7 is a sectional view taken along line VII-VII of FIG. 6; and

FIG. 8 is a sectional view taken along line VIII-VIII of FIG. 6.

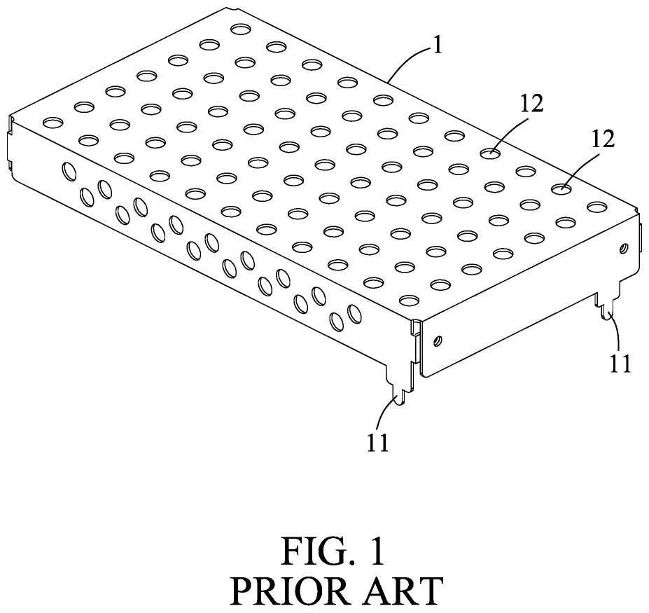

### DETAILED DESCRIPTION

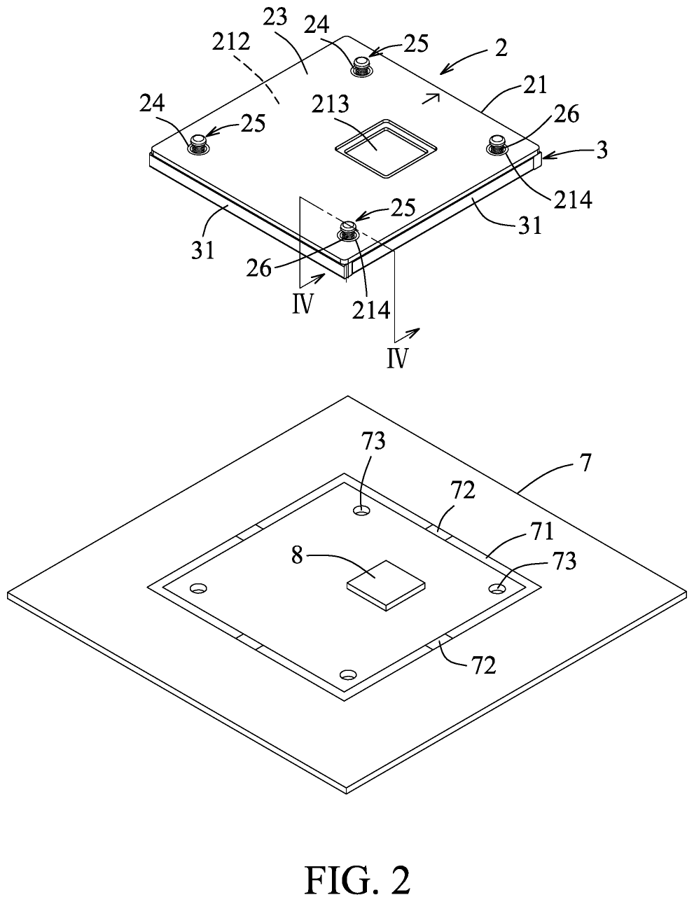

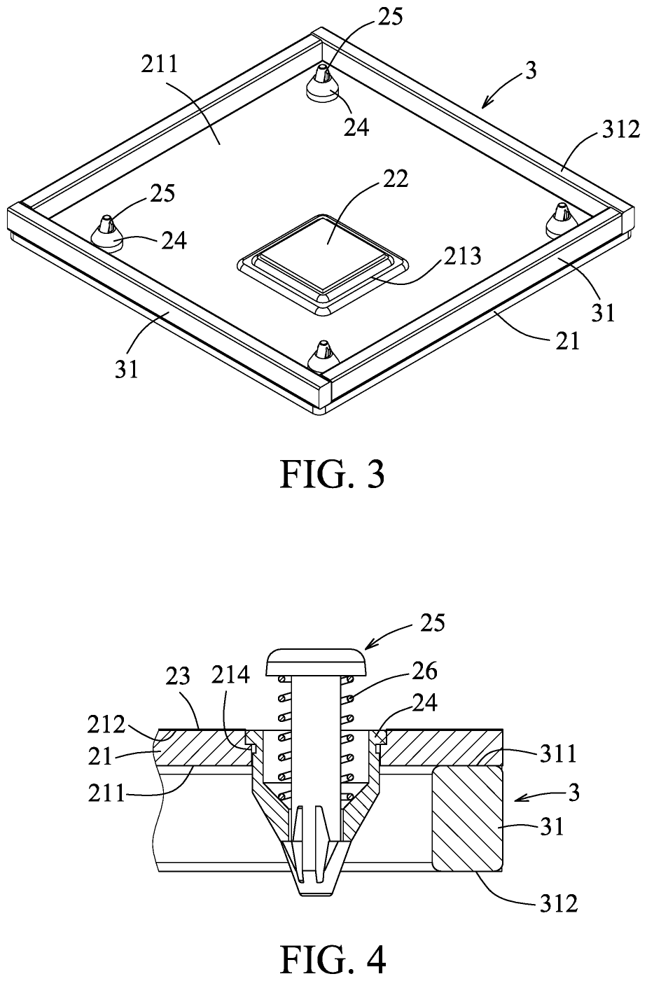

Referring to FIGS. 2 to 4, an embodiment of an electromagnetic shield according to the disclosure is adapted for use inside an electronic device with wireless communication capabilities, especially with Bluetooth and wireless network functions. The electromagnetic shield is adapted to be mounted on a circuit board 7 within the electronic device and to cover an electronic component 8 disposed on the circuit board 7 so as to shield electromagnetic radiation produced by the electronic component 8. The circuit board 7 has a receiving area 71, a plurality of copper foils 72 disposed in the receiving area 71 and acting as electronic ground, and four securing holes 73 respectively formed in four corner portions of the receiving area 71. In this embodiment, the electronic component 8 is exemplified as a System on a Chip (SOC), but is not limited to this. In certain embodiments, the electronic component 8 may be a synchronous dynamic random-access memory device, a flash memory device, an embedded storage device, or other electronic devices that may produce electromagnetic radiation noise. The electromagnetic shield includes a cover unit 2, and a conductive surrounding wall 3 connected between the cover unit 2 and the circuit board 7.

The cover unit 2 includes a metallic main body 21, a thermal conducting plate 22, a thermal radiation film 23, a plurality of sleeve members 24, a plurality of securing members 25, and a plurality of springs 26. In this embodiment, the cover unit 2 includes four sleeve members 24, and four securing members 25. In this embodiment, regarding the material of the main body 21, aluminum is chosen for the lower price, the lighter weight and the fact that it is easy to process. The main body 21 has a first surface 211, a second surface 212 that is opposite to the first surface 211, an abutment portion 213 that protrudes from the first surface 211, and four through holes 214 respectively disposed in four corner portions of the main body 21 and extending from the first surface 211 to the second surface 212. In this embodiment, the abutment portion 213 is produced by stamping, and is adapted to be connected to the electric component 8. The thermal conducting plate 22 is disposed on the abutment portion 213 and is adapted to abut against the electronic component 8 such that heat produced by the electronic component 8 may be transmitted by heat conduction through the thermal conducting plate 22 to the main body 21. The thermal radiation film 23 covers the second surface 212 of the main body 21 for facilitating dissipation of heat which is generated by the electronic component 8.

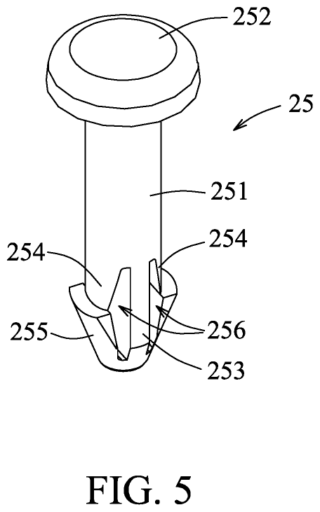

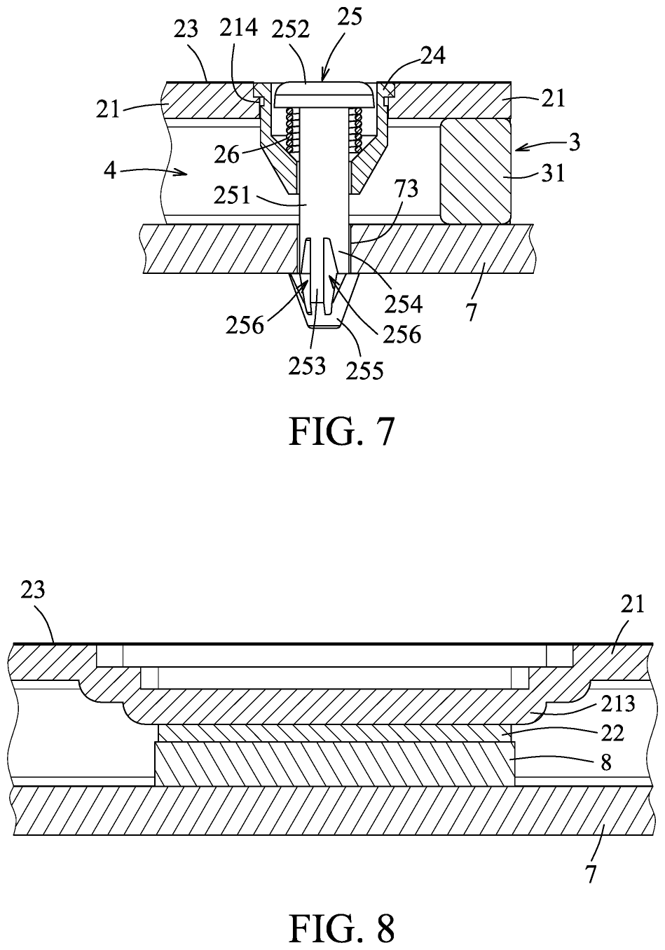

In this embodiment, the through holes 214 of the main body 21 are respectively aligned with the securing holes 73 of the circuit board 7. The sleeve members 24 are mounted to the main body 21 and respectively disposed in the through holes 214. In other embodiments, the sleeve members 24 may be molded as one piece with the main body 21. The securing members 25 extend through the main body 21 and respectively through the sleeve members 24, and are connected to the circuit board 7 to thereby secure the main body 21 and the conductive surrounding wall 3 to the circuit board 7. In this embodiment, the securing members 25 are made of a flexible plastic. Further referring to FIGS. 5 and 7, each of the securing members 25 has a cylindrical body 251, a head portion 252 connected to an end of the cylindrical body 251, an extending portion 253 connected to an opposite end of the cylindrical body 251, two branch portions 254 connected to the opposite end of the cylindrical body 251 and spaced apart from and disposed at opposite sides of the extending portion 253, and a limiting portion 255 connected to the extending portion 253 and the branch portions 254. The extending portion 253 extends through a respective one of the securing holes 73 of the circuit board 7. The limiting portion 255 has a frustoconical shape which converges in a direction away from the branch portions 254, and is adapted to be disposed on a side surface of the circuit board 7 which is opposite to said conductive surrounding wall 3. The branch portions 254 are adapted to extend through the respective one of the securing holes 73 of the circuit board 7. The extending portion 253, the limiting portion 255 and the branch portions 254 cooperatively define two inner spaces 256. The inner spaces 256 provide space for the limiting portion 255 to deform into when the limiting portion 255 is under pressure.

The conductive surrounding wall 3 is made of a low-density and compressible material. In this embodiment, the conductive surrounding wall 3 has four straight conductive foam blocks 31 coupled together to form a rectangular structure, but is not limited in this respect. In certain embodiments, the conductive surrounding wall 3 may have only one annular conductive foam block 31. Each conductive foam block 31 has first and second surfaces 311, 312 opposite to each other. The first surface 311 of each conductive foam block 31 is connected to the main body 21 by a conductive double-sided tape (not shown) , and the second surface 312 of each conductive foam block 31 is adapted to abut tightly against the side surface of the circuit board 7 and is electrically connected to a respective one of the copper foils 72.

In this embodiment, the cover unit 2 further includes four springs 26. Each of the springs 26 is sleeved on the cylindrical body 251 of a respective one of the securing members 25 and is connected between a respective one of the securing members 25 and a respective one of the sleeve members 2 for bringing the circuit board 7 to tightly contact the conductive surrounding wall 3. Specifically, each spring 26 has opposite ends respectively abutting against the head portion 252 of the respective one of the securing members 25 and the respective one the sleeve members 24. The springs 26 are adapted for biasing the respective one of the limiting portions 255 to abut tightly against the side surface of the circuit board 7 and for bringing the circuit board 7 to tightly contact the conductive surrounding wall 3.

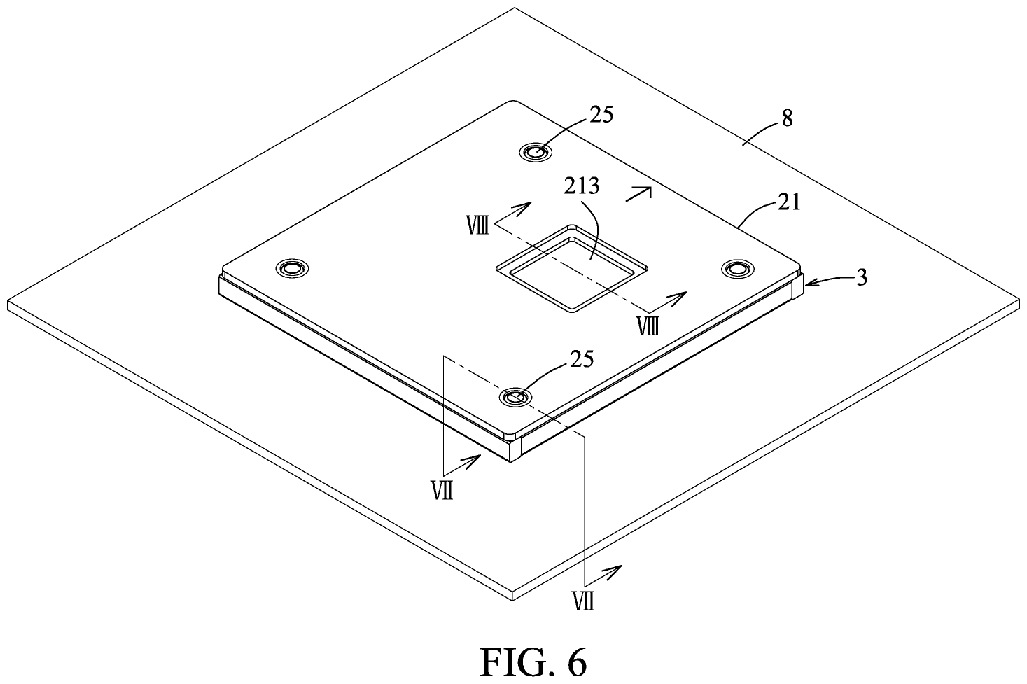

Referring to FIGS. 6 to 8, when installing the electromagnetic shield to the circuit board 7, the securing members 25 are applied to extend respectively through the securing holes 73. As each of the securing members 25 is passing through the respective one of the securing holes 73, a pressure is applied to the limiting portion 255 of the securing members 25 by a hole-defining surface which defines the respective one of the securing holes 73, such that each of the limiting portions 255 are deformed inwards towards the inner spaces 256, causing the branch portions 254 to also deform inwards. When the limiting members 255 are fully passed through the circuit board 7, the branch portions 254 help to restore the limiting members 255 to an original form. Each of the springs 26 is pressed by the head portion 252 of the respective one of the securing members 25 and is compressed, pushing against the respective one of the sleeve members 24 and applying a pressure to the head portion 252 of the respective one of the securing members 25, biasing the limiting portion 255 of the respective one of the securing members 25 to abut tightly against the side surface of the circuit board 7. At the same time, the springs 26 also apply a pressure to the respective one of sleeve members 24, causing the main body 21 to press down on the conductive surrounding wall 3. The conductive surrounding wall 3 is thus compressed to abut tightly against the circuit board 7, disallowing gaps from forming between the circuit board 7 and the conductive surrounding wall 3. At this point, the conductive surrounding wall 3, the main body 21 and the circuit board 7 cooperatively define an electromagnetic shielding space 4 that encloses the electronic component 8. Either low-frequency or high-frequency noise radiation produced by the electronic component 8 is prevented from transmitting out of the electromagnetic shielding space 4 and interfering with other electronic devices. Further, the thermal conducting plate 22 on the abutment portion 213 of the main body 21 abuts against the electronic component 8, allowing the heat produced from the electronic component 8 to transfer to the main body 21 and be dissipated, cooling the electronic component 8.

In the description above, for the purposes of explanation, numerous specific details have been set forth in order to provide a thorough understanding of the embodiment(s). It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. An electromagnetic shield adapted to be mounted on a circuit board and to cover an electronic component disposed on the circuit board so as to shield electromagnetic radiation produced by the electronic component, said electromagnetic shield comprising:
a cover unit including a metallic main body having a first surface, a second surface that is opposite to said first surface, and an abutment portion that protrudes from said first surface, and that is adapted to be connected to the electronic component; and
a conductive surrounding wall connected to said cover unit, adapted to abut tightly against the circuit board, and adapted to cooperate with said main body and the circuit board to define an electromagnetic shielding space that encloses the electronic component.

2. The electromagnetic shield as claimed in claim 1, wherein said conductive surrounding wall is made of a low-density and compressible material.

3. The electromagnetic shield as claimed in claim 1, wherein said cover unit further includes a thermal radiation film covering said second surface of said main body for facilitating dissipation of heat which is generated by the electronic component.

4. The electromagnetic shield as claimed in claim 1, wherein said cover unit further includes a thermal conducting plate disposed on said abutment portion and adapted to abut against the electronic component.

5. The electromagnetic shield as claimed in claim 1, wherein said cover unit further includes a plurality of securing members adapted to secure said main body and said conductive surrounding wall to the circuit board.

6. The electromagnetic shield as claimed in claim 5, wherein said cover unit further includes:
a plurality of sleeve members mounted to said main body, said securing members extending through said main body and respectively through said sleeve members, and adapted to be connected to the circuit board; and
a plurality of springs, each of which is connected between a respective one of said securing members and a respective one of said sleeve members for bringing the circuit board to tightly contact said conductive surrounding wall.

7. The electromagnetic shield as claimed in claim 6, wherein:
each of said securing members has
a cylindrical body,
a head portion connected to an end of said cylindrical body,
an extending portion connected to an opposite end of said cylindrical body and extending through a respective one of securing holes of the circuit board, and
a limiting portion connected to said extending portion and adapted to be disposed on a side surface of the circuit board which is opposite to said conductive surrounding wall; and
each of said springs is sleeved on said cylindrical body of the respective one of said securing members, has opposite ends respectively abutting against said head portion of the respective one of said securing members and the respective one said sleeve members, and is adapted for biasing the respective one of said limiting portions to abut tightly against the side surface of the circuit board.

8. The electromagnetic shield as claimed in claim 7, wherein:
each of said securing members further has two branch portions connected to said opposite end of said cylindrical body and connected between said cylindrical body and said limiting portion, spaced apart from and disposed at opposite sides of said extending portion, and adapted to be disposed in the respective one of the securing holes of the circuit board; and
said extending portion, said limiting portion and said branch portions cooperatively define two inner spaces that provides space for said limiting portion to deform when said limiting portion is under pressure.
